(19) United States
(12) Patent Application Publication
(10) Pub. No.: US 2004/0252562 A1
(43) Pub. Date: Dec. 16, 2004

(54) Set top box capable of performing wireless transmission

(75) Inventor: Kun-tae Kim, Suwon-si (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD.

(21) Appl. No.: 10/761,190

(22) Filed: Jan. 22, 2004

(30) Foreign Application Priority Data
Jun. 12, 2003 (KR) 2003-37832

(51) Int. Cl. G11C 7/00

(52) U.S. Cl. 365/200

(57) ABSTRACT

Provided is a set top box capable of performing wireless transmission. The set top box includes an advanced television system committee (ATSC) receiver, a transport (TS) stream converting unit, and a wireless processing module. The ATSC receiver converts a tuned digital broadcasting signal into a TS stream. The TS stream converting unit converts a high definition (HD) image signal input from outside into a standard definition (SD) image signal and then converts the SD image signal into the TS stream. The wireless processing module wirelessly processes an output of the ATSC receiver or an output of the TS stream converting unit and transmits the processed output.

### CROSS REFERENCE TO RELATED APPLICATION

This application claims the priority of Korean Patent Application No. 2003-37832, filed on Jun. 12, 2003, in the Korean Intellectual Property Office, the disclosure of which is hereby incorporated by reference in its entirety.

### BACKGROUND OF THE INVENTION

1. Field of the Invention

Apparatuses and methods consistent with the present invention relate to an image signal processor, and more particularly, to a set top box capable of performing wireless transmission.

2. Description of the Related Art

Regular televisions are standardized to process analog broadcasting signals.

As satellite broadcasting and other digital broadcasting are becoming prevalent, a separate converting device called a set top box is provided to process digital broadcasting signals compressed/transmitted in accordance with moving picture experts group (MPEG) and to convert the digital broadcasting signals into analog broadcasting signals, so that users can watch digital broadcasting presented by an analog television.

The set top box converts digital-format image signals, such as cable television broadcasting signals and satellite broadcasting signals, into analog-format image signals, thus allowing the analog television to process the digital-format image signals. With the recent demand for digital broadcasting among consumers, the set top box is becoming increasingly widespread.

FIG. 1 is a block diagram of a conventional set top box (STB). The conventional set top box includes a tuner 100, a signal separating unit 101, an audio signal processing unit 102, a video signal processing unit 103, a display quality correcting unit 104, a digital-to-analog converter (DAC) 105, a control unit 106, and a memory 107.

The tuner 100 is a vestigial side band (VSB) tuner. The tuner 100 receives a radio frequency (RF) signal transmitted as a ground wave signal, performs error correction and decoding, and outputs a pure MPEG-2 signal to the signal separating unit 101.

The signal separating unit 101 separates an MPEG-2 video signal and an MPEG-2 audio signal from the MPEG-2 signal output from the tuner 100 and outputs the MPEG-2 audio signal to the audio signal processing unit 102 and outputs the MPEG-2 video signal to the video signal processing unit 103.

The audio signal processing unit 102 processes the MPEG-2 audio signal such that the MPEG-2 audio signal can be audible. The video signal processing unit 103 decodes the MPEG-2 video signal and outputs the resulting signal to the display quality correcting unit 104.

The display quality correcting unit 104 corrects display error during MPEG-2 compression or transmission, thus preventing degradation of display. The DAC 105 converts a signal output from the display quality correcting unit 104 into an analog signal and outputs the analog signal to a monitor (not shown).

The control unit 106 controls the overall operation of the set top box. The memory 107 stores operating programs required for the operation of the set top box and other various data.

U.S. Pat. No. 6,233,695 discloses the conventional set top box.

As such, in order to receive digital broadcasting, a dedicated digital broadcasting receiver must be used or a set top box for receiving digital broadcasting must be mounted. A digital set top box is connected to a television by a wire, and an external device such as a digital video disk (DVD) player is also connected to the set top box or television by a wire, which results in complex wiring. As wall-mount type televisions have come into wide use, it is necessary to consider a counterplan for simpler wiring of the set top box and wall-mount type televisions.

Also, since a high definition (HD) image signal input to the set top box from outside cannot be converted into a standard definition (SD) transport stream (hereinafter “TS” or “TS stream”) image signal, a range of input image sources is inevitably limited.

### SUMMARY OF THE INVENTION

The present invention provides a set top box capable of performing wireless transmission by wirelessly transmitting a digital broadcasting signal and converting a high definition (HD) image signal input from outside into a standard definition (SD) transport stream image signal.

According to one aspect of the present invention, there is provided a set top box capable of performing wireless transmission. The set top box comprises an advanced television system committee (ATSC) receiver, a transport stream converting unit, and a wireless processing module. The ATSC receiver converts a tuned digital broadcasting signal into a TS stream. The TS stream converting unit converts a high definition (HD) image signal input from outside into a standard definition (SD) image signal and then converts the SD image signal into the TS stream. The wireless processing module wirelessly processes an output of the ATSC receiver or an output of the TS stream converting unit and transmits the processed output.

The set top box further comprises a switching unit which selects one of the output of the ATSC receiver or the output of the TS stream converting unit.

The set top box further comprises a decoding unit which decodes the TS stream selected by the switching unit and outputs the decoded TS stream to an image device connected to the set top box by a wire.

The TS stream converting unit comprises a converter and an encoding unit. The converter converts the HD image signal input from outside into the SD image signal. The encoding unit converts the SD image signal input from outside or the output of the converter into the TS stream.

The converter comprises an analog-to-digital converter (ADC) and a down converter. The ADC converts the HD image signal input from outside into a digital signal. The down converter converts the HD image signal converted into the digital signal into the SD image signal.

### BRIEF DESCRIPTION OF THE DRAWINGS

The above and other aspects and advantages of the present invention will become more apparent by describing in detail an exemplary embodiment thereof with reference to the attached drawings in which:

FIG. 1 is a block diagram of a conventional set top box;

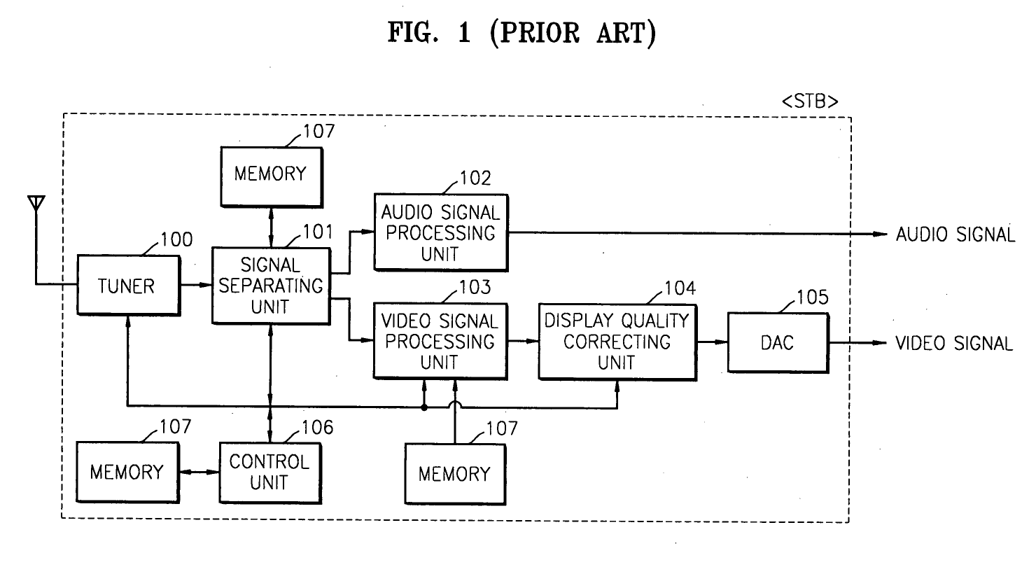

FIG. 2 is a conceptual view of a set top box capable of performing wireless transmission; and

FIG. 3 is a block diagram of a set top box capable of performing wireless transmission according to the present invention.

### DETAILED DESCRIPTION OF THE INVENTION

The present invention will now be described more fully with reference to the accompanying drawings, in which an exemplary embodiment of the invention is shown.

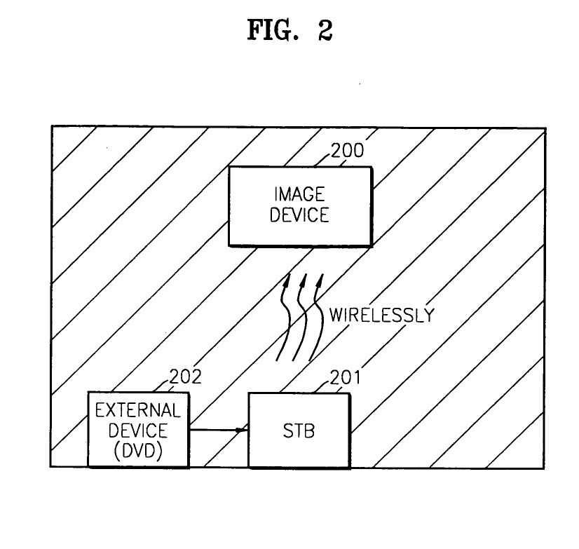

FIG. 2 is a conceptual view of a set top box capable of performing wireless transmission. In FIG. 2, an image device 200, a set top box (STB) 201, and an external device (DVD) 202 are illustrated.

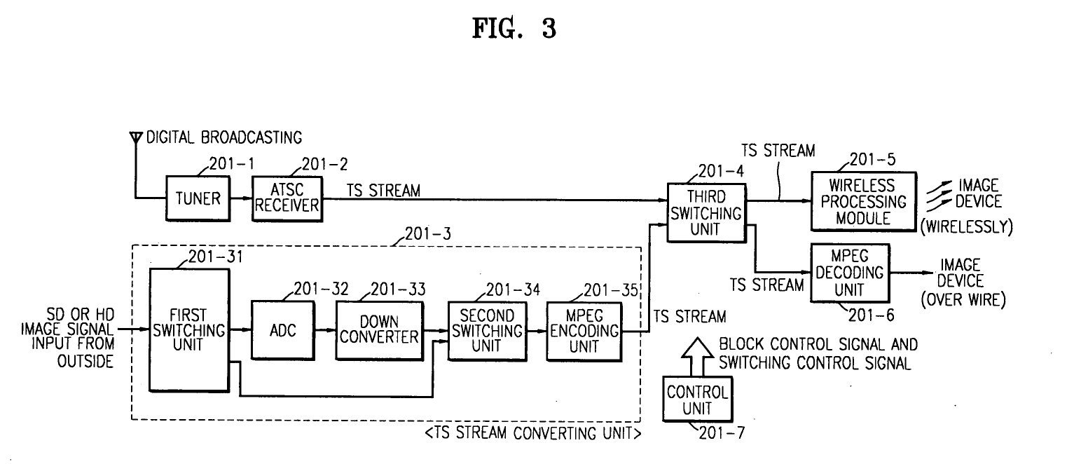

FIG. 3 is a block diagram of a set top box capable of performing wireless transmission according to the present invention. The set top box of FIG. 3 includes a tuner 201-1, an advanced television system committee (ATSC) receiver 201-2, a transport stream converting unit 201-3, a third switching unit 201-4, a wireless processing module 201-5, an MPEG decoding unit 201-6, and a control unit 201-7.

In the present invention, the TS stream converting unit 201-3 includes a first switching unit 201-31, an analog-to-digital converter (ADC) 201-32, a down converter 201-33, a second switching unit 201-34, and an MPEG encoding unit 201-35.

Hereinafter, the present invention will be described in detail with reference to FIGS. 2 and 3.

As shown in FIG. 2, the STB 201 of the present invention is connected to the external device (DVD) 202, which reproduces an HD (480p) or SD (480i) image signal, by a wire, but is wirelessly connected to the image device 200.

Although not shown in figures, the image device 200 of the present invention performs a series of processes for receiving a wireless signal transmitted from the STB 201 and displaying the received wireless signal. Also, the STB 201 may be connected to the image device 200 by a wire, and the image device 200 may be connected to the external device (DVD) 202 by a wire.

The STB 201 converts a received digital broadcasting signal into a TS stream, wirelessly processes the TS stream, and transmits the TS stream to the image device 200 or decodes the TS stream and then transmits the decoded TS stream to the image device 200 over the wire. Also, the STB 201 converts the HD (480p) or SD (480i) image signal received from the external device (DVD) 202 into a SD (480i) TS stream, wirelessly processes the SD (480i) TS stream, and transmits the SD (480i) TS stream to the image device 200 or decodes the SD (480i) TS stream and then transmits the decoded SD (480i) TS stream to the image device 200 over the wire.

The control unit 201-7 controls the overall operation of the set top box 201 and outputs a switching control signal that controls switching operations of the first switching unit 201-31, the second switching unit 201-34, and the third switching unit 201-4.

The tuner 201-1 is a vestigial side band (VSB) tuner. The tuner 201-1 receives a digital broadcasting signal transmitted as a ground wave signal, and the ATSC receiver 201-2 converts the tuned digital broadcasting signal into a TS stream and outputs the TS stream.

The ATSC (Advanced Television System Committee) is an international organization founded to establish technical standards of advanced TV systems and also represents established technical standards. The core parts of these standards concern video and audio compression and transmission, in which an image signal is compressed to an MPEG-2 format signal, audio and voice signals are compressed to AC-3 format signals, and transmission thereof is performed using a vestigial side band (VSB) technique.

The TS stream converting unit 201-3 converts the HD (480p) or SD (480i) image signal, input from the external device (DVD) 202, into the SD (480i) TS stream.

The first switching unit 201-31 selects the HD (480p) or SD (480i) image signal, input from outside in response to the switching control signal of the control unit 201-7. The first switching unit 201-31 outputs the HD (480p) image signal, input from outside, to a converter including the ADC 201-32 and the down converter 201-33. The first switching unit 201-31 outputs the SD (480i) image signal, input from outside, to the second switching unit 201-34. Although a digital-to-analog converter (DAC) is not shown in figures, the SD (480i) image signal input from outside is converted into the SD (480i) image signal in digital format, and the SD (480i) image signal is output to the second switching unit 201-34.

The converter including the ADC 201-32 and the down converter 201-33 converts the HD (480p) image signal, selected by the first switching unit 201-31, into the SD (480i) image signal.

The ADC 201-32 converts the HD (480p) image signal into a three-channel 8-bit HD (480p) image signal in digital format.

The down converter 201-33 converts the three-channel 8-bit HD (480p) image signal into the SD (480i) image signal. In general, a progressive scanning technique involves progressively transmitting information of images rather than transmitting information of images at the same time. On the other hand, an interlaced scanning technique involves forming a frame by scanning information of images twice—by scanning the odd numbered lines in the first field, and then scanning the even numbered lines in the second field, thereby filling in gaps between the odd numbered lines. The down converter 201-33 converts the HD (480p) image signal into the SD (480i) image signal by separating fields from the HD (480p) image signal, and then transmitting the separated fields.

The second switching unit 201-34 selects the SD (480i) image signal in digital format, output from the first switching unit 201-31 in response to the switching control signal of the control unit 201-7, or selects an output signal of the down converter 201-33 and outputs the SD (480i) image signal or the output signal of the down converter 201-33 to the MPEG encoding unit 201-35.

The MPEG encoding unit 201-35 encodes the SD (480i) image signal in digital format, selected and output by the first switching unit 201-31, into the TS stream and encodes the HD (480p) image signal, converted into the SD (480i) image signal, into the TS stream.

The third switching unit 201-4 selects the TS stream of a digital broadcasting signal, output from the ATSC 201-2 in response to the switching control signal of the control unit 201-7, or selects the TS stream output from the MPEG encoding unit 201-35 and outputs the TS stream to the wireless processing module 201-5 or the MPEG decoding unit 201-6.

When the TS stream is transmitted wirelessly, the third switching unit 201-4 selects the TS stream of the digital broadcasting signal output from the ATSC 201-2 or selects the TS stream output from the MPEG encoding unit 201-35 and outputs the TS stream to the wireless processing module 201-5.

When the TS stream is transmitted over the wire, the third switching unit 201-4 selects the TS stream of the digital broadcasting signal output from the ATSC 201-2 or selects the TS stream output from the MPEG encoding unit 201-35 and outputs the TS stream to the MPEG decoding unit 201-6.

The wireless processing module 201-5 wirelessly processes the TS stream of the digital broadcasting signal, a TS stream of an analog broadcasting signal, and a TS stream of an external input image signal and transmits them to the image device 200. The outputted TS stream is transmitted as an electromagnetic wave. In one embodiment, the outputted TS stream is transmitted in the radio frequency range. In another embodiment, the outputted TS stream is transmitted in a frequency range or a wavelength range outside the radio frequency range, including infrared, ultraviolet, etc.

The MPEG decoding unit 201-6 decodes the TS stream of the digital broadcasting signal, the TS stream of the analog broadcasting signal, and the TS stream of the external input image signal and transmits them to the image device 200 over the wire.

As described above, according to the present invention, the set top box is wirelessly connected to the external device and the television, thus simplifying wiring. Also, a range of different types of input image sources can be enlarged by converting the HD image signal, input to the set top box from outside, into the SD TS stream image signal and transmitting the SD TS stream image signal wirelessly.

While the present invention has been particularly shown and described with reference to an exemplary embodiment thereof, it will be understood by those of ordinary skill in the art that various changes in form and details may be made therein without departing from the spirit and scope of the invention as defined by the appended claims and their equivalents.

What is claimed is:

1. A set top box capable of performing wireless transmission, the set top box comprising:
a digital television receiver, which converts a tuned digital broadcasting signal into a first transport stream (TS);
a TS converting unit, which receives at least one of a high definition (HD) image signal input from outside and an external SD image signal input from outside, converts the HD image signal into a standard definition (SD) image signal if the HD image signal is received, and then converts one of the SD image signal and the external SD image signal into a second TS; and
a wireless processing module, which processes one of the first TS and the second TS as a processed output and wirelessly transmits the processed output.

2. The set top box of claim 1 further comprising a switching unit which receives the first TS and the second TS and outputs one of the first TS and the second TS as an output of the switching unit.

3. The set top box of claim 2 further comprising a decoding unit which decodes the output of the switching unit and outputs a decoded TS stream to an image device connected to the set top box by a wire.

4. The set top box of claim 1, wherein the TS converting unit comprises:
a converter, which converts the HD image signal input from outside into the SD image signal and outputs the SD image signal as an output of the converter; and
an encoding unit, which converts the external SD image signal input from outside or the output of the converter into the second TS.

5. The set top box of claim 4, wherein the converter comprises:
an analog-to-digital converter (ADC), which converts the HD image signal input from outside into a digital signal; and
a down converter, which converts the HD image signal converted into the digital signal into the SD image signal.

6. The set top box of claim 3, wherein the wireless processing module wirelessly transmits the processed output in a radio frequency range.

7. The set top box of claim 5, wherein the wireless processing module wirelessly transmits the processed output in a radio frequency range.

8. The set top box of claim 3, wherein the digital television receiver is an advanced television system committee (ATSC) receiver.

9. The set top box of claim 5, wherein the digital television receiver is an advanced television system committee (ATSC) receiver.

10. A method for performing wireless transmission of television signals comprising:
receiving a digital broadcasting signal and converting the digital broadcasting signal into a first transport stream (TS);
receiving at least one of an external high definition (HD) image signal and an external standard definition (SD) image signal, converting the external HD image signal into an internal SD image signal if the external HD image signal is received, and converting one of the internal SD image signal and the external SD image signal into a second TS; and
transmitting one of the first TS and the second TS over a wireless medium.

11. The method as claimed in claim 10 further comprising decoding one of the first TS and the second TS and transmitting a decoded signal to an image device through a wire.

12. The method as claimed in claim 10, wherein converting one of the internal SD image signal and the external SD image signal into a second TS comprises encoding one of the external SD image signal and the internal SD image signal into the second TS.

13. The method as claimed in claim 12, wherein the converting the external HD image signal into an internal SD image signal comprises:
converting the external HD image signal into a digital signal; and
down converting the digital signal into the internal SD image signal.

14. The method of claim 11, wherein the transmitting one of the first TS and the second TS over the wireless medium is done at a radio frequency.

15. The method of claim 13, wherein the transmitting one of the first TS and the second TS over the wireless medium is done at a radio frequency.
